(19) United States
(12) Patent Application Publication
(10) Pub. No.: US 2013/0258561 A1
(43) Pub. Date: Oct. 3, 2013

(54) ELECTRONIC COMPONENT WITH GUIDING ELEMENT

(71) Applicant: XING-HUA TANG, Shenzhen City (CN)

(72) Inventor: XING-HUA TANG, Shenzhen City (CN)

(21) Appl. No.: 13/629,487

(22) Filed: Sep. 27, 2012

(30) Foreign Application Priority Data
Apr. 3, 2012 (CN) 201210095725.4

(51) Int. Cl. H05K 5/02

(52) U.S. Cl. 361/679.01

(57) ABSTRACT

An electronic component includes a component body and at least one guiding element. The component body includes a number of sides. The at least one guiding element is placed on at least one side of the component body. A user can quickly and easily determine orientation of the electronic component by touch when mounting the electronic component in a socket.

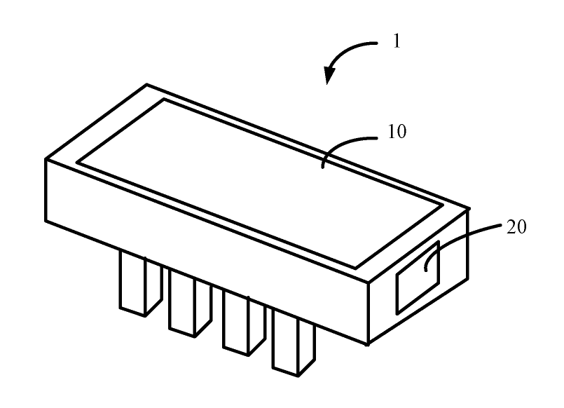

### BACKGROUND

1. Technical Field

The present disclosure relates to electronic components.

2. Description of Related Art

Printed circuit boards (PCBs) are a necessary part of many electronic devices, such as mobile phones, digital cameras, and electronic readers. A number of electronic components, such as chips, may need to be installed in sockets of the PCB. Such installation requires an operator to compare pins of the electronic component with the sockets of the PCB to find the correct socket and properly orient the component for insertion, which consumes time and may be boring for the operator.

An electronic device with guiding element, to overcome the described limitations is thus needed.

### BRIEF DESCRIPTION OF THE DRAWING

Many aspects of the present disclosure are better understood with reference to the following drawing. The components in the drawing are not necessarily drawn to scale, the emphasis instead being placed upon clearly illustrating the principles of the present disclosure. Moreover, in the drawing, like reference numerals designate corresponding parts throughout the view.

The FIGURE is a schematic diagram of an electronic component with guiding element, in accordance with an exemplary embodiment.

### DETAILED DESCRIPTION

Embodiments of the present disclosure will be described with reference to the accompanying drawing.

The FIGURE illustrates an electronic component 1, which includes a component body 10 and at least one guiding element 20. The component body 10 includes a number of sides. In the embodiment, the electronic component 1 has one guiding element 20, and the component body 10 has four sides. The guiding element 20 is located on one side of the component body 10. The component element 20 is tactile and provided for guiding the user to correctly place the electronic component 1 into corresponding sockets of a PCB (not shown).

In the embodiment, the guiding element 20 may be an embossed or engraved area of the side of the component body 10 so that it can be easily sensed by a user's finger. The guiding element 20 embossing or engraving may be in the form of a logo of the manufacturer, a model number, or other desired design.

In the embodiment, the guiding element 20 can be located at any side of the component body 10.

In another embodiment, there are two guiding elements 20, which are placed on two adjacent sides of the component body 10 respectively.

Use of one or more guiding elements 20 allow a user to easily feel the orientation of the component 1 so that it can be installed without having to take the time to examine the pins of the electronic component 1.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. An electronic component with guiding element, comprising:
a component body comprising a plurality of sides; and
at least one guiding element placed on at least one side of the component body.

2. The electronic component according to claim 1, wherein the surface of the guiding element is an embossed or engraved area.

3. The electronic component with guiding element according to claim 2, wherein the guiding element embossing or engraving in the form of a logo of the manufacturer or a model number.

4. The electronic component with guiding element according to claim 1, wherein the number of the at least one guiding element is one and the guiding element is located on any side of the component body.

5. The electronic component with guiding element according to claim 1, wherein the number of the at least one guiding element is two, the two guiding elements are placed on two adjacent sides of the component body respectively.
